(19) United States
(12) Patent Application Publication
(10) Pub. No.: US 2022/0336704 A1
(43) Pub. Date: Oct. 20, 2022

(54) SILICON DOUBLE-WAFER SUBSTRATES FOR GALLIUM NITRIDE LIGHT EMITTING DIODES

(71) Applicant: Tectus Corporation, Saratoga, CA (US)

(72) Inventor: Paul Scott Martin, Palo Alto, CA (US)

(21) Appl. No.: 17/726,361

(22) Filed: Apr. 21, 2022

Related U.S. Application Data
(63) Continuation of application No. PCT/US2022/024506, filed on Apr. 12, 2022.
(60) Provisional application No. 63/176,085, filed on Apr. 16, 2021.

(51) Int. Cl. H01L 33/32; H01L 33/00; H01L 27/15

(52) U.S. Cl. CPC H01L 33/32; H01L 33/0093; H01L 33/007; H01L 33/0095; H01L 27/156

(57) ABSTRACT

Two, standard dimension, Si wafers, one <111>-oriented and the other <100>-oriented for example, are bonded together to form a two-ply substrate. Such an Si double-wafer substrate is stiffer than either a double-thickness <111>-oriented or <100>-oriented wafer. C-beveling on the two constituent wafers results in a B-bevel edge of the two-ply substrate that does not create stress risers. Also, standard thickness wafers are commercially available. GaN epitaxial layer is then grown on this two-ply substrate.

### CROSS-REFERENCE TO RELATED APPLICATION(S)

This application is a continuation of International Application No. PCT/US2022/024506, “Silicon Double-Wafer Substrates for Gallium Nitride Light Emitting Diodes,” filed Apr. 12, 2022; which claims priority under 35 U.S.C. § 119(e) to U.S. Provisional Patent Application Ser. No. 63/176,085, “Si Double-Wafer GaN Substrate,” filed Apr. 16, 2021. The subject matter of all of the foregoing is incorporated herein by reference in its entirety.

### BACKGROUND

### 1. Technical Field

This disclosure relates generally to gallium nitride light emitting diodes.

### 2. Description of Related Art

A “femtoprojector” is a small projector that projects images from an image source contained inside a contact lens onto a user's retina. The image source and associated optical system are small enough to fit inside a contact lens. To meet this size requirement while still achieving reasonable resolution, the pixel sizes in the image source typically are much smaller than in image sources for other applications. For example, a conventional LED direct emission display uses discrete red, green, and blue emitting LEDs with resolutions of up to 500 pixels per inch (composite white pixels/inch) and about a 25 um (micron) pitch from one colored pixel to the neighboring color pixel. In contrast, an LED array for a femtoprojector preferably has pixel sizes of less than 1 um² in emitting area with a pixel pitch of 2 um or less.

Gallium nitride is a material system that may be used to construct LEDs. What is needed are fabrication processes suitable for making GaN light emitting diodes in large quantities.

### BRIEF DESCRIPTION OF THE DRAWINGS

Embodiments of the disclosure have other advantages and features which will be more readily apparent from the following detailed description and the appended claims, when taken in conjunction with the examples in the accompanying drawings, in which:

FIG. 1 illustrates a <111> silicon wafer substrate bonded to a <100> silicon wafer substrate.

FIG. 2 illustrates the structure of FIG. 1 after approximately 6 um of epitaxial GaN growth on the top of the <111> silicon wafer.

FIG. 3 illustrates the structure of FIG. 2 after all but approximately 30-50 um of the <100> silicon wafer has been removed, for example by grinding.

FIG. 4 illustrates the structure of FIG. 3 after the remaining approximately 30-50 um of the <100> silicon wafer has been removed, for example by chemical mechanical polishing.

### DETAILED DESCRIPTION OF THE PREFERRED EMBODIMENTS

The figures and the following description relate to preferred embodiments by way of illustration only. It should be noted that from the following discussion, alternative embodiments of the structures and methods disclosed herein will be readily recognized as viable alternatives that may be employed without departing from the principles of what is claimed.

Gallium nitride (GaN) light emitting diodes (LEDs) may be used in ultra-dense microdisplays with pixel pitches in the range from about 0.5 um to about 5.0 um. Before the pixels of a display are defined by lithographic processes in a semiconductor device fabrication facility, thin layers of GaN are created on a silicon (Si) crystalline substrate by epitaxial deposition. “Epitaxial” means that the GaN layers are formed with a defined crystal orientation with respect to the Si substrate. Epitaxial growth of GaN on <111>-oriented Si is performed at high temperatures in the range from about 800 C to 1100 C.

The emission wavelength of a GaN LED is sensitive to growth temperature. A change of just one degree Celsius leads to a wavelength change of about 5 nm. During epitaxial growth of GaN on Si, the Si substrate wafer sits on a SiC heater. Any variation or gap in the distance between the heater and the wafer leads to temperature differences across the wafer surface. Since Si and GaN have different coefficients of thermal expansion, these temperature variations lead to stress and wafer bow.

Even though GaN can be grown on <111>-oriented Si, the crystal structures and lattice constants of the two materials are not matched. GaN growth on an Si surface begins as islands which later coalesce into a film. In the initial island phase, the strain on the substrate created by the structural mismatch is significant compared to Young's modulus of the substrate. The strain is greater for larger diameter substrates.

This effect and the consequences of uneven heating mentioned above both mean that it is highly desirable for the Si substrate to be as flat and stiff as possible during GaN epitaxial growth. The simplest way to achieve stiffness is to increase wafer thickness. High volume semiconductor manufacturing is done today on standard size 300 mm diameter wafers. A 300 mm diameter wafer that is 1.55 mm thick would be stiff enough for GaN epitaxial growth.

However, it is difficult to manufacture LEDs by growing a GaN epitaxial layer on a 300 mm diameter, 1.55 mm thick, <111>-oriented Si wafer, for the following reasons. First, 300 mm diameter, 1.55 mm thick, <111>-oriented Si wafers generally are not commercially available. Tools that polish 300 mm diameter wafers are designed for the weight of wafers that are 0.775 mm thick. It is difficult to handle double the weight. There is no commercial incentive to modify the polishing tools because the demand for <111> wafers is so small compared to that for <100> wafers used in CMOS processes. Second, after epitaxial growth, the Si substrate would be thinned to the standard 0.775 mm thickness in order to be compatible with state-of-the-art lithography tools. The thinning process leaves a sharp edge around the wafer circumference, and the sharp edge leads to cracks in the wafer due to stress left from the GaN growth process. Third, the stiffness of a <111> wafer is not as great as that of a <100> wafer.

Thus, lack of availability of thick <111> wafers, incompatibility with state-of-the-are manufacturing tools and facilities, and relative fragility compared to <100> wafers are all issues that prevent high-volume production of ultra-dense microdisplays.

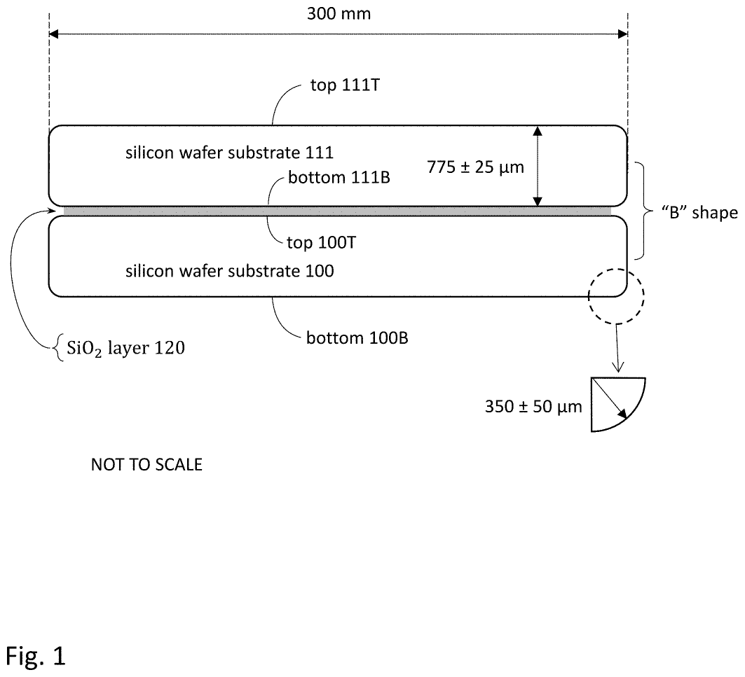

As shown in FIG. 1, a solution to the problem is to bond two, standard dimension, Si wafers, one <111>-oriented and the other <100>-oriented, together to form a two-ply substrate. Such an Si double-wafer substrate is stiffer than either a double-thickness <111>-oriented or <100>-oriented wafer. C-beveling on the two constituent wafers results in a B-bevel edge of the two-ply substrate that does not create stress risers. Also, standard thickness wafers are commercially available.

In FIG. 1, the two wafers 111, 100 are standard dimensions: nominally 300 mm diameter and 0.775 mm thickness. Both wafers 111, 100 are C-beveled, with radius of curvature of approximately 350 um of each edge. The top wafer 111 is <111>-oriented silicon and the bottom wafer 100 is <100>-oriented silicon. The wafers 111, 100 may be referred to as wafer substrates, since they form a substrate for an epitaxial layer.

The two wafers 111, 100 are bonded together such that the top side 100T (the side with no wafer ID mark etched on it) of the <100> wafer is bonded to the bottom side 111B (with wafer ID mark) of the <111> wafer. This leaves the pristine top side 111T of the <111> wafer available for GaN growth. An intermediate layer of at least 100 nm of a SiO₂ layer 120 is grown on the top side 100T of the <100> wafer. The bottom 111B of the <111> wafer does not have SiO₂ grown on it, but its native, 40 nm thick, oxide is present, leading to a total oxide thickness between the two wafers of about 140 nm. Bonding is performed at room temperature. Subsequently, the bonded wafers 111,100 may be annealed, for example at about 400 C for about 60 minutes. The process has been tested experimentally with good results.

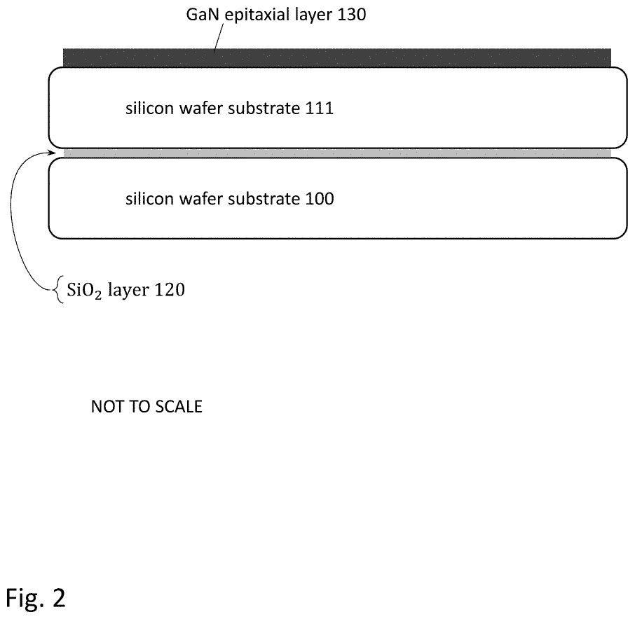

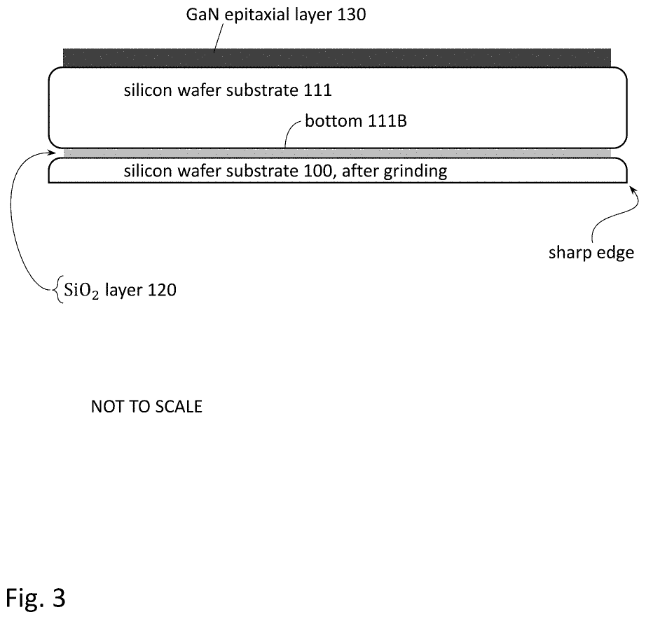

After the two wafers 111,100 are bonded together, approximately 6 um of epitaxial GaN 130 is grown on the top of the <111> silicon wafer, as shown in FIG. 2. Next, most of the <100> silicon wafer is ground off. All but about 30-50 um of the <100> silicon wafer is removed. Note that grinding leaves a sharp edge, as shown in FIG. 3. This accentuates mechanical stress. At this point, the wafer ID mark on bottom side 111B is not readable.

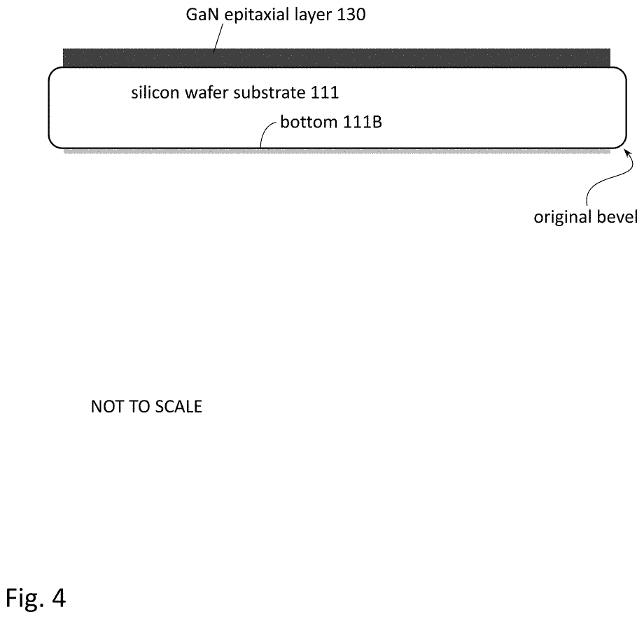

Finally the rest of the <100> silicon wafer is removed by chemical mechanical polishing (CMP), as shown in FIG. 4. The CMP process stops at the SiO₂ layer 120 between the wafers, thus preserving the original C-bevel edge of the <111> silicon wafer and preventing damage to it. The original C-bevel edge allows the wafer to proceed through normal processing tools without risk of cracking the wafer or damaging the tools. The wafer ID mark on bottom side 111B is readable.

After the <100> wafer is removed, the GaN-on-<111> wafer is ready for processing in state-of-the-art, 300 mm processing facilities. Starting with a GaN-on-<111> wafer that is compatible with modern, high-volume fabs, production of microdisplays in vast quantities becomes possible. The GaN epitaxial layer 130 is patterned into an array of GaN LEDs and connected to driver circuitry. For femtoprojectors, which may be incorporated into contact lenses, the pixel pitch of the GaN LED array may be 5 um or less. For example, see U.S. patent application Ser. No. 17/154,480, “Ultra-dense array of LEDs with half cavities and reflective sidewalls, and hybrid bonding methods,” which is incorporated herein by reference.

In an alternate process to the one described above, the two silicon wafers are bonded together without an intervening oxide. In this process, the bonded wafers are annealed at temperatures greater than about 1,000 C.

Although the detailed description contains many specifics, these should not be construed as limiting the scope of the invention but merely as illustrating different examples. It should be appreciated that the scope of the disclosure includes other embodiments not discussed in detail above. For example, the bottom <100>-oriented wafer may instead be another <111>-oriented wafer or other silicon wafer. Various other modifications, changes and variations which will be apparent to those skilled in the art may be made in the arrangement, operation and details of the method and apparatus disclosed herein without departing from the spirit and scope as defined in the appended claims. Therefore, the scope of the invention should be determined by the appended claims and their legal equivalents.

What is claimed is:

1. A semiconductor structure comprising:
a first <111>-oriented silicon (Si) wafer substrate;
a second Si wafer substrate bonded to the <111>-oriented Si wafer substrate; and
a gallium nitride (GaN) epitaxial layer grown on the <111>-oriented Si wafer substrate.

2. The semiconductor structure of claim 1 wherein each Si wafer substrate has a C-bevel edge and the semiconductor structure has a B-bevel edge.

3. The semiconductor structure of claim 1 further comprising:
an intermediate silicon dioxide (SiO₂) layer between the first Si wafer substrate and the second Si wafer substrate.

4. The semiconductor structure of claim 3 wherein the intermediate SiO₂ layer has a thickness of at least 100 nm.

5. The semiconductor structure of claim 1 wherein a top side of the second Si wafer substrate is bonded to a bottom side of the first Si wafer substrate, and bottom sides of both Si wafer substrates contain a wafer ID mark.

6. The semiconductor structure of claim 1 wherein each Si wafer substrate is a 300 mm diameter wafer substrate.

7. The semiconductor structure of claim 1 wherein a thickness across the two Si wafer substrates is at least 1.55 mm.

8. The semiconductor structure of claim 1 wherein a thickness of the GaN epitaxial layer is not more than 10 um.

9. The semiconductor structure of claim 1 wherein a thickness of the <111>-oriented Si wafer substrate is approximately 0.775 mm.

10. The semiconductor structure of claim 1 wherein the second Si wafer substrate is a <100>-oriented Si wafer substrate.

11. The semiconductor structure of claim 1 wherein the second Si wafer substrate is a <111>-oriented Si wafer substrate.

12. A method for manufacturing gallium nitride (GaN) LED arrays, the method comprising:
manufacturing a precursor comprising:
a first <111>-oriented silicon (Si) wafer substrate;
a second Si wafer substrate bonded to the <111>-oriented Si wafer substrate; and
a gallium nitride (GaN) epitaxial layer grown on the <111>-oriented Si wafer substrate; and
patterning the GaN epitaxial layer into an array of GaN LEDs.

13. The method of claim 12 wherein the array of GaN LEDs has a pixel pitch of not more than 5 um.

14. The method of claim 12 wherein manufacturing the precursor comprises:
bonding a top side of the second Si wafer substrate to a bottom side of the first Si wafer substrate; and
growing the gallium nitride (GaN) epitaxial layer on a top side of the first Si wafer substrate.

15. The method of claim 14 wherein the bonding occurs at room temperature.

16. The method of claim 14 further comprising:
annealing the bonded Si wafer substrates.

17. The method of claim 14 wherein bonding the top side of the second Si wafer substrate to the bottom side of the first Si wafer substrate comprises:
growing an intermediate silicon dioxide (SiO₂) layer on the bottom side of the first Si wafer substrate; and
bonding the top side of the second Si wafer substrate to the bottom side of the first Si wafer substrate with the intermediate SiO₂ layer therebetween.

18. The method of claim 14 wherein the Si wafer substrates are bonded together without growing an intermediate oxide layer.

19. The method of claim 12 further comprising:
prior to patterning the GaN epitaxial layer, grinding away silicon from the second Si wafer substrate starting from the bottom side of the second Si wafer substrate, but leaving a top side and some silicon remaining.

20. A method for manufacturing gallium nitride (GaN) LED arrays, the method comprising:
bonding a top side of a <100>-oriented Si wafer substrate to a bottom side of a <111>-oriented Si wafer substrate; wherein each Si wafer substrate is C-beveled, the two bonded Si wafer substrates are B-beveled, and a bottom side of each Si wafer substrate contains a wafer ID mark;
growing a gallium nitride (GaN) epitaxial layer on a top side of the <111>-oriented Si wafer substrate;
removing silicon from the <100>-oriented Si wafer substrate starting from the bottom side of the <100>-oriented Si wafer substrate, but leaving a top side and some silicon remaining;
chemical mechanical polishing to remove the remaining silicon of the <100>-oriented Si wafer substrate, exposing the SiO₂ layer so that the wafer ID mark on the bottom side of the <111>-oriented Si wafer substrate is readable; and
patterning the GaN epitaxial layer into an array of GaN LEDs.

21. The method of claim 20 wherein each Si wafer substrate is a standard size 300 mm diameter, 0.775 mm thick wafer when bonded together.
